(19) United States
(12) Patent Application Publication
(10) Pub. No.: US 2025/0392303 A1
(43) Pub. Date: Dec. 25, 2025

(54) POWER-ON-RESET CIRCUIT WITH IMPROVED RESPONSIVENESS

(71) Applicant: Attopsemi Technology Co., LTD, HSINCHU (TW)

(72) Inventors: Shine C. Chung, San Jose, CA (US); Te Lou, Taipei City (TW)

(73) Assignee: Attopsemi Technology Co., LTD, HSINCHU (TW)

(21) Appl. No.: 18/753,905

(22) Filed: Jun. 25, 2024

(51) Int. Cl. H03K 17/14; H03K 5/24; H03K 17/22; H03K 19/0185

(52) U.S. Cl. CPC H03K 17/145; H03K 5/2481; H03K 17/223; H03K 19/018528

(57) ABSTRACT

A Power-On Reset (POR) design that provides a sharply rising signal when a supply voltage VDD ramps up from 0V to a pre-determined value for system reset. The POR design has at least one of sense amplifier (SA) bias circuit, a SA reference circuit, a SA target circuit, and a SA. When VDD ramps up, the SA bias circuit, the SA reference circuit, the SA target circuit, and the SA are turned on. The SA is configured to receive a SA reference input and a SA target input and to compare the SA reference input with the SA target input to generate a SA output. The SA output can rise sharply when VDD reaches a predetermined value. The SA output can be buffered to generate a POR signal.

### BACKGROUND OF THE RELATED ART

Power-On Reset (POR) is a circuit to go from zero (0) Volts (V) to a high voltage sharply when a supply voltage VDD ramps from 0V to reach a pre-determined value. POR can be used to reset latches or flip-flops to start system initialization, such as generating a system clock, reading system parameters from storages, and reset state machines to the idle mode, etc.

FIG. 1 shows a portion of a timing waveform 10 when a supply voltage VDD is ramping up. The VDD 11 is ramping up from 0V to a final voltage. During VDD ramping, a Power-On-Reset (POR) 12 can stay at 0V initially and rise sharply to a logic high voltage when VDD reaches a pre-determine value, e.g. 1.2V. If the VDD ramps up very rapidly, POR may rise after VDD reaches the stable voltage. A desirable POR should not closely follow VDD ramping up or otherwise rise slowly.

Typically, there are two types of POR circuits, namely delay and voltage reference circuits to generate a POR. FIG. 2 shows a delay type of POR 15 that has a resistor 16 coupled to a capacitor 17 between a supply voltage VDD and ground GND. The intermediate node Vx between the resistor 16 and capacitor 17 is used as an input to an inverter 18 and the output of the inverter 18 is used as an input to another inverter 19. The output of the inverter 19 can be a POR. This circuit basically counts on the resistor 16 and capacitor 17 as a RC element to charge up Vx and then to sharpen the waveform of Vx by two inverters 18 and 19. The time delay to turn on a POR depends on the RC time constant. If the VDD ramping is very slow, e.g. 10 ms, the values of R and C need to be very large, which makes the implementation impractical. There are many variants of delay type of POR that includes a diode or MOS to turn on/off capacitor charging. But these types of POR design tend to be limited to rather fast ramping rates, such as 100 us or less, and the area to build the resistor 16 and capacitor 17 is rather large.

FIG. 3 shows a voltage reference circuit used as POR 20. The POR 20 has a left branch that has a resistor 21 R2 coupled between VDD and Vin; another resistor 22 R1 coupled between Vin and an emitter of a bipolar device 23 Q1; the bipolar device 23 has a base and collector coupled to 0V; and another resistor 24 R3 coupled between Vin and 0V. The POR 20 also has a right branch that has a resistor 31 R2 coupled between VDD and Vip; a bipolar device 33 Q2 having an emitter coupled to Vip and a base and collector coupled to 0V; and a resistor 34 R3 coupled between Vip and 0V. The resistance R3 tends to be much larger than either R1 or R2. The emitter area of bipolar 33 tends to be integer multiply (e.g., 8) of the bipolar 23. The voltages Vin and Vip are used as input to an operational amplifier (OPAMP) 40 with an output to an inverter 50 to generate a POR. When the supply voltage VDD is ramping up, Vip voltage tends to be higher than Vin until VDD is high enough that Vin can be equal or higher than Vip. At that time, the OPAMP 40 output goes low and a POR goes to a high voltage. This POR is a modification of a bandgap reference to generate a POR. This bandgap-based POR is disadvantageous because it requires bipolar devices and complex analog circuits such as OPAMP.

Neither the delay type 15 nor the voltage reference type 20 of POR in FIGS. 2 and 3, respectively, are able to adequately satisfy modern requirements for a POR circuit. Thus, there is a need for an improved POR circuit that can better achieve the modern requirements, such precision turn-on voltage, wide VDD ramping rate, zero standby and low transient current, small area, and re-generation upon VDD dips, etc.

### SUMMARY

A Power-On Reset (POR) circuit that is based on a high-gain circuit to trigger a sharp transition when a supply voltage VDD ramps up from 0V to reach a pre-determined value is disclosed. One embodiment can be a sense amplifier (SA) bias circuit coupled to a SA reference circuit and then the SA reference circuit coupled to a SA target circuit and to a SA. The SA has an output coupled to a buffer circuit block to generate a POR. When VDD is at 0V, the SA bias circuit, SA reference circuit, SA target circuit, and SA are all off, and the SA output is at 0V. When VDD ramps up and reaches to a pre-determined voltage that SA starts to sense resistance, current, or voltage correctly, and the SA output can be switched to a logic high level. The SA output can be used to generate a POR after proper buffering. The POR can also be used to power down at least one of the SA bias circuit, SA reference circuit, SA target circuit, and SA after going through a power-off circuit. Since the SA can have very high gain, the POR transitions from 0V to a high voltage can be very sharp. Also, if desired, all logic circuits can be designed and implemented in standard CMOS process without the need for complex analog circuits.

In one embodiment in method, a POR, Power-On Reset, can be generated during VDD ramping by starting at least one sense amplifier (SA) bias circuit, SA reference circuit, SA target circuit, and SA. The SA output is kept low when VDD is a ground voltage or 0V. When VDD reaches a voltage higher enough, the SA can be turned on to sense the resistance, current, or voltage difference between the reference and the target in the SA output correctly. After sensing, the SA output can rise sharply. With proper buffering, the SA output can be used as a POR. The SA bias circuit, the SA reference circuit, the SA target circuit, and the SA can also be turned off by the POR through a power-off circuit for zero standby current.

The invention can be implemented in numerous ways, including as a method, system, device, or apparatus (including computer readable medium). Several embodiments of the invention are discussed below.

As a POR circuit block integrated in an integrated circuit, one embodiment of the invention can, for example, include at least: at least one sense amplifier (SA) bias circuit; at least one sense amplifier (SA) reference circuit coupled to the SA bias circuit and configured to produce a reference signal; at least one sense amplifier (SA) target circuit coupled to the SA bias circuit and configured to produce a target input signal; and at least one sense amplifier circuit coupled to the SA reference circuit to receive the reference signal and coupled to the SA target circuit to receive the target input signal, the at least one sense amplifier circuit configured to provide a SA output signal based on a comparison of the reference signal and the target input signal.

As an electronic system, one embodiment can, for example, include at least: a processor or a random logic block; and at least one Power-On Reset (POR) circuit block operatively connected to the processor or random logic. The at least one POR circuit block can, for example, include at least: at least one sense amplifier (SA) reference circuit configured to produce a reference signal; at least one sense amplifier (SA) target circuit configured to produce a target input signal; and at least one sense amplifier circuit coupled to the SA reference circuit to receive the reference signal and coupled to the SA target circuit to receive the target input signal, the at least one sense amplifier circuit configured to provide a SA output signal based on a comparison of the reference signal and the target input signal.

As a method for providing a POR signal in an integrated circuit, one embodiment of the invention can, for example, include at least: producing a bias input; producing a reference signal based on the bias input; producing a target signal based one the bias input; generating, via at least a sense amplified circuit included within the integrated circuit, an sense amplifier output signal based on at least the reference signal and the target signal; and buffering the sense amplifier output signal to generate the POR signal. In one implementation, the POR signal can be configured to transition from approximately 0V to approximately VDD abruptly when a supply voltage VDD ramps up from 0 V to a pre-determined value. As a POR circuit, one embodiment can, for example, include at least one sense amplifier (SA) bias circuit, SA reference circuit, SA target circuit, and SA. When VDD is at ground level (0V), the SA output is at 0V. With VDD ramping up, the SA bias circuit, the SA reference circuit, the SA target circuit and the SA are turned on sequentially. When VDD reaches a voltage higher enough that the SA can sense the differential resistance, current, or voltage between the SA reference and the SA target in the SA, the SA output goes high. This SA output can be used as a POR after proper buffering and to turn off the SA bias circuit, the SA reference circuit, the SA target circuit and the SA after going through a power-off circuit.

As an electronic system, one embodiment can, for example, include at least a processor, a random logic block, and a POR block operatively connected to the processor. The POR block can include at least one sense amplifier (SA) bias circuit coupled to at least one SA reference circuit, and SA target circuit, and which is coupled to at least one SA. The SA output can be at 0V when VDD is at ground voltage. With the VDD ramping up, the SA bias circuit, the SA reference circuit, the SA target circuit, and the SA are turned on sequentially. When the VDD reaches to a pre-determined voltage, the SA can be turned on to sense the differential resistance, current, or voltage between reference and target branches and to raise the SA output to logic high voltage abruptly. The SA output can be coupled to a buffer circuit block to generate a POR signal. At the same time, the POR signal or SA output can be used to turn off the SA bias circuit, the SA reference circuit, the SA target circuit, and the SA going through a power-off circuit for zero standby current. The POR signal can be used to reset latches, flip-flops, and state machines in the processor or random logic.

As a method for providing a POR, one embodiment can, for example, include at least providing a sense amplifier (SA) bias circuit, a SA reference circuit, a SA target circuit, and a SA coupled to each other in sequence. The SA output is initially at 0V, or logic low. When the VDD is ramping up, the SA bias circuit, the SA reference circuit, the SA target circuit, and the SA are turned on in sequences. When the VDD reaches to a pre-determined voltage, the SA can sense the differential resistance, current, or voltage between the reference and the target branches correctly and to raise the main SA output to a high voltage abruptly. The SA output can be coupled to a buffer circuit to generate a POR. At the same time, the POR signal or SA output can be used to turn off the SA bias circuit, the SA reference circuit, the SA target circuit and the SA after going through a power-off circuit for zero standby current.

### BRIEF DESCRIPTION OF THE DRAWINGS

The present invention will be readily understood by the following detailed descriptions in conjunction with the accompanying drawings, wherein like reference numerals designate like structural elements, and in which:

FIG. 1 shows a portion of a timing waveform of VDD ramping and POR generation.

FIG. 2 shows a portion of a schematic of a delay type of POR.

FIG. 3 shows a portion of a schematic of a voltage reference POR.

FIG. 4 shows a portion of a block diagram of a POR according to one embodiment.

FIG. 5(a) shows a portion of a schematic of a POR based on cascode sense amplifier, corresponding to the POR in FIG. 4, according to one embodiment.

FIG. 5(b) shows a portion of a schematic of a POR based on current-mirrored sense amplifier, corresponding to the POR in FIG. 4, according to another embodiment.

FIG. 6(a) shows a portion of a schematic of a POR based on a latch-type of SA, corresponding to the POR in FIG. 4, according to one embodiment.

FIG. 6(b) shows a portion of a schematic of a POR based on a latch-type of SA, corresponding to the POR in FIG. 4, according to another embodiment.

FIG. 7 shows a portion of a schematic of a power-down generation circuit, corresponding to the POR in FIG. 4, according to one embodiment.

FIG. 8(a) shows a portion of a schematic of a startup circuit for a CMOS PTAT, corresponding to the CMOS PTAT in FIG. 5(b), according to one embodiment.

FIG. 8(b) shows a portion of a schematic of a startup circuit for a CMOS PTAT, corresponding to the CMOS PTAT in FIG. 5(b), according to another embodiment.

FIG. 9(a) shows a portion of a schematic of a startup signal generation, corresponding to the startup signals of a CMOS PTAT in FIG. 8(b), according to one embodiment.

FIG. 9(b) shows a portion of a schematic of a startup signal generation, corresponding to the startup signals of a CMOS PTAT in FIG. 8(b), according to another embodiment.

FIG. 10(a) shows a flow chart of a POR generation procedure upon power ramping up, according to one embodiment.

FIG. 10(b) shows a flow chart of power-down signal generation, according to one embodiment.

FIG. 10(c) shows a flow chart of startup signal generation, according to one embodiment.

FIG. 11(a) shows a processor electronic system that employees at least one POR block with at least one processor according to one embodiment.

FIG. 11(b) shows an electronic system that employees at least one POR block with at least one random logic block according to another embodiment.

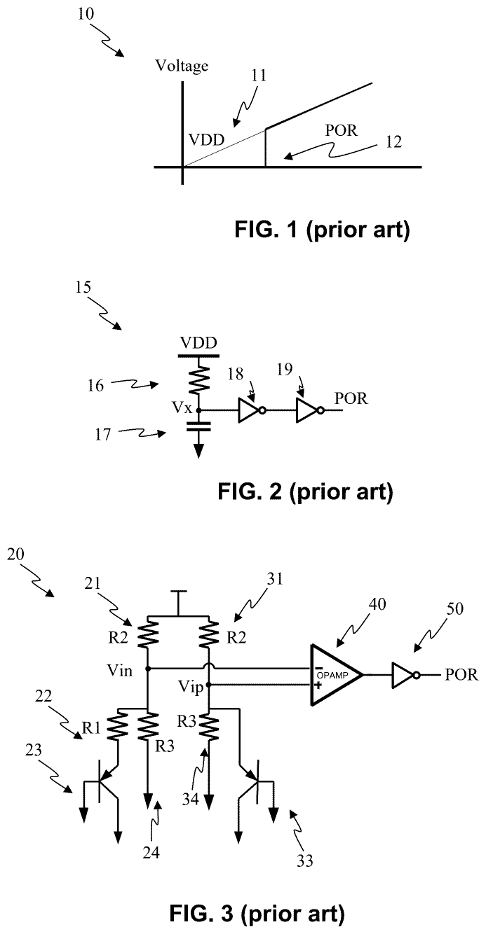

### DETAILED DESCRIPTION OF THE INVENTION

A Power-On Reset (POR) having a circuit to generate an abrupt rising signal when a supply voltage VDD is ramping from 0V to a pre-determined voltage is disclosed. In one embodiment, the POR can have at least one sense amplifier (SA) bias circuit, a SA reference circuit, a SA target circuit, and a SA to sense differential resistance, current, or voltage between the reference and the target branches and to raise the SA output when VDD is ramping higher enough to make SA sense data correctly. Initially, all nodes are at ground level, or 0V, when VDD is at 0V. When VDD is ramping up, the SA bias, SA reference, SA target and main SA start to turn on one by one. When VDD reaches a pre-determined voltage, the SA can sense the data correctly to raise the SA output to a logic high voltage. Optionally, the POR can also be used to cutoff the power of the SA bias circuit, the SA reference circuit, the SA target circuit, and the SA through a power-off circuit.

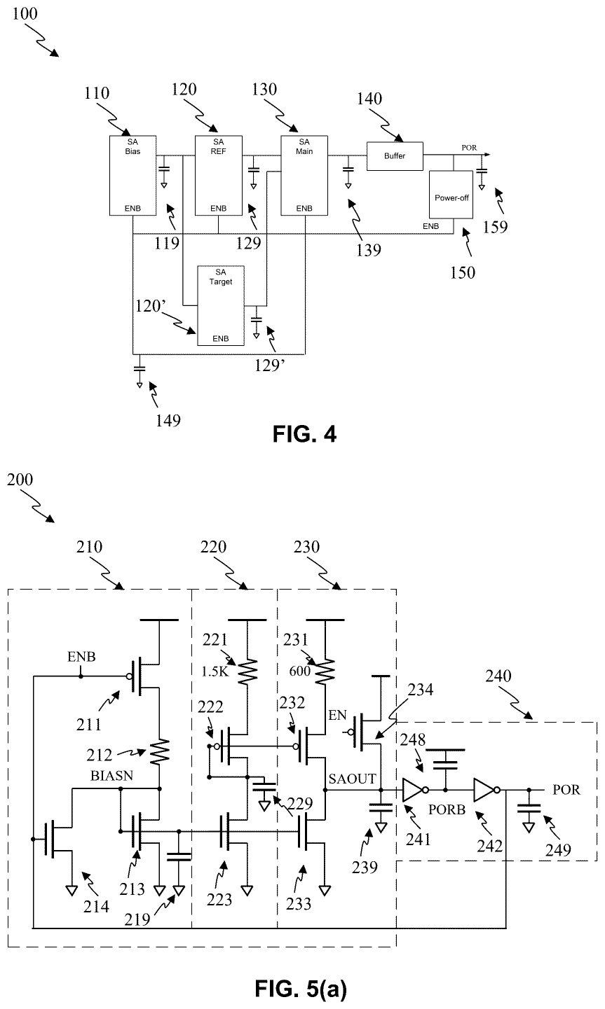

FIG. 4 shows a portion of a block diagram of a POR 100, according to one embodiment of the invention. The POR generation 100 has at least one sense amplifier (SA) bias circuit 110 coupled to at least one SA reference circuit 120, and then coupled to a SA 130. The SA bias circuit 110 can also be coupled to at least one SA target circuit 120′ and then coupled to the SA 130. The output of the SA 130 can be coupled to at least one buffer circuit 140 that has an output as a POR signal. The POR 100 can also include a power-off block 150 that can generate ENB, Enable Bar, to cutoff the power of the SA bias circuit 110, the SA reference circuit 120, the SA target circuit 120′, and the SA 130. The SA output or the POR can be used to power down the SA blocks in another embodiment. The blocks SA bias circuit 110, the SA reference circuit 120, the SA reference 120′ circuit, the SA 130, the buffer block 140 or the power-off block 150 and the POR can have at least one decoupling capacitor 119, 129, 129′, 139, 149, and 159, respectively, to hold the block output low and to prevent the signals from following VDD during ramping.

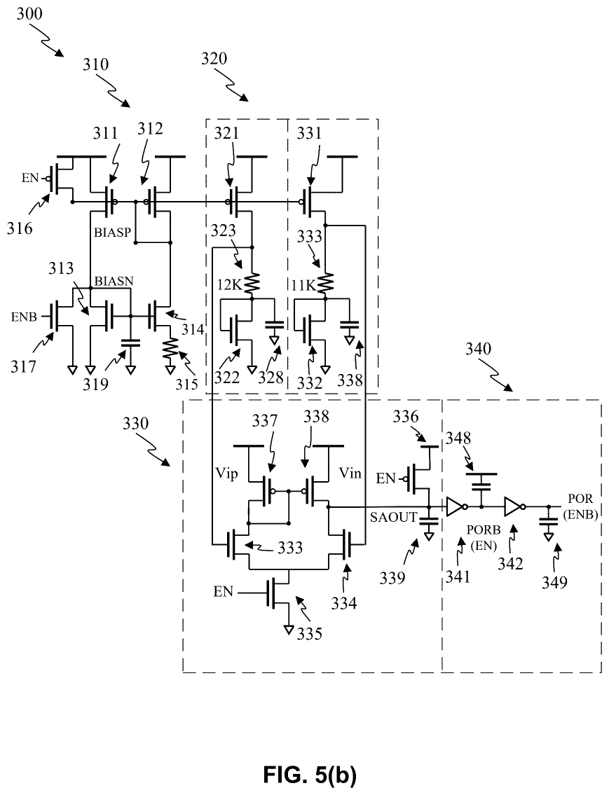

FIG. 5(a) shows a portion of a schematic of a POR 200 according to one embodiment of the invention. The POR 200 has a SA bias circuit 210 coupled to a SA reference circuit 220. The SA reference circuit 220 is coupled to a SA 230. The SA 230 output SAOUT can be coupled to a buffer block 240 to generate a POR. The SA bias circuit 210 can have a PMOS 211 with a source, gate, and drain coupled to VDD, ENB and a bias resistor 212, respectively. The bias resistor 212 has the other end BIASN coupled to a drain of a NMOS 213, whose gate and source coupled to BIASN and ground GND (or 0V), respectively. The gate of the NMOS 213 is coupled to a drain of a power down NMOS 214, whose gate and source are coupled to ENB and GND, respectively. The SA reference 220 has a 1.5K resistor 221 coupled to VDD and to a source of a PMOS 222, whose gate and drain are coupled together to a drain of a current-mirrored NMOS 223, whose gate and source are coupled to BIASN and GND, respectively. The SA 230 can have a 600 ohm target resistor 231 coupled between VDD and a source of PMOS 232, whose gate and drain coupled to the gate of the cascode device 222 and drain of another current-mirrored NMOS 233. The gate and source of the NMOS 233 are coupled to BIASN and GND, respectively. The drain of the NMOS 233 is an output SAOUT of the SA 230 that can be coupled to an input of an inverter 241, whose output PORB is further coupled to an input of another inverter 242 to generate a POR. There can be at least one decoupling capacitor 219, 229, 239, and 249 coupled to the output of the SA bias 210, SA reference 220, SA 230, and buffer 240, respectively, to GND and to hold the enable bar ENB and/or output nodes low during VDD ramping up. In this embodiment, resistance 231 is the only component in the target circuit, and MOS 232 and 233 are the only components in the main SA. Together they can be built in one branch between VDD and ground. There can be another decoupling capacitor 248 coupled between PORB and VDD to keep PORB high during ramping before POR is triggered. The reference and target resistance of 1.5K and 600 ohm are provided as non-limiting examples, as various other values can be used. The SA block disable signal ENB can be coupled to POR directly or POR through another power-off block in different embodiments.

In FIG. 5(a), SA bias 210 shows a NMOS diode-connected bias generation using a PMOS 211 for enabling. The NMOS 213 is to generate a bias current that can be mirrored to NMOS 223 in SA reference circuit 220 and NMOS 233 in SA 230 to provide currents for reference and SA branches, respectively. The PMOS 222 is diode-connected to provide bias for a cascode device, PMOS 232. The reference resistance 221 and the target resistance 231 are 1.5K and 600 ohm, respectively, for example. With this configuration, the SA output SAOUT can be high when the SA bias circuit 210, the SA reference circuit 220, and the SA 230 are all turned on and the VDD reaches to a voltage higher enough to sense differential resistance successfully, by pulling SAOUT high. SAOUT also has a PMOS pullup 234 with a gate coupled to EN to pull to VDD after finishing sensing. SA output SAOUT can be buffered by inverters 241 and 242 to generate a POR. POR can also be used as ENB and PORB used as EN to cutoff the power of the SA bias circuit 210, the SA reference circuit 220, and the SA 230. The POR can also go through another power-off circuit to cutoff the power of the SA bias 210, the SA reference 220, and the SA 230 in another embodiment. The decoupling capacitors 219, 229, 239, and 249 can be coupled to GND and the capacitor 248 can be coupled to VDD to activate the desired functions and to be large to reduce noise during VDD ramping.

FIG. 5(b) shows a portion of a schematic of a POR 300 according to another embodiment of this invention. The POR 300 has a SA bias circuit 310 coupled to a SA refence/target circuit 320. The SA reference/target circuit 320 is coupled to a SA 330. The output of the SA 330 SAOUT is coupled to a buffer block 340 to generate a POR signal as its output. The SA bias circuit 310 is can be CMOS PTAT (Proportional To Absolute Temperature) circuit. The left branch of the PTAT has a PMOS 311 with a source, gate, and drain coupled to VDD, BIASP and BIASN, respectively. NMOS 313 has a source, gate, and drain coupled to GND, BIASN, and BIASN, respectively. The right branch has a PMOS 312 with source, gate, and drain coupled to VDD, BIASP, and BIASP, respectively. The NMOS 314 has source, gate, and drain coupled to a bias resistor 315, BIASN, and BIASP, respectively. The bias resistor 315 has the other end coupled to GND. The BIASP and BIASN has a pullup PMOS 316 and a pulldown NMOS 317 with gates coupled to EN and ENB, respectively, to cutoff the PTAT power after generating a POR signal. The SA reference/target circuit 320 has a reference branch that has a PMOS 321 with source, gate, and drain coupled to VDD, BIASP, and a reference resistor 323. The reference resistor 323 can be coupled to a drain and gate of a NMOS 322, whose source is coupled to GND. There is another target branch in SA reference/target circuit 320 that has a PMOS 331 with a source, gate, and drain coupled to VDD, BIASP, and a target resistor 333. The target resistor 333 can be coupled to a drain and gate of a NMOS 332, whose source is coupled to GND. For example, the reference resistance of 323 and the target resistance of 333 can be 12K and 11K, respectively, to provide differential resistance for sensing. The SA 330 also has a current-mirrored SA that has a pair of current mirrors PMOS 337 and 338 with sources coupled to VDD and drains coupled to the drains of another pair of NMOS 333 and 334, respectively. The PMOS 337 has gate coupled to drain and then coupled to a gate of PMOS 338. The gates of NMOS 333 and 334 are coupled to the output of the SA reference branch Vip and SA target branch Vin, respectively, whose sources are coupled to a drain of a tail NMOS 335. The tail NMOS 335 has a gate and source coupled to EN and GND, respectively, to supply current for the current-mirrored SA 330. The SA output SAOUT has a PMOS pullup to VDD whose gate is coupled to EN to pull the SAOUT to logic high after the SA is powered off. SA output SAOUT can go through two stages of inverters 341 and 342 to generate a PORB and POR in a buffer block 340, respectively. The PORB and POR can serve as enable and enable bar, EN and ENB, respectively, to cutoff the power for SA bias 310, SA reference/target circuit 320, and SA 330. The EN and ENB can also be generated from a power-off block triggered by the POR or SAOUT in another embodiment. There are decoupling capacitors 319, 328, 338, 339, and 349 coupled to GND as enable bar ENB and/or in the output of the SA bias 310, SA reference/target circuit 320, and SA 330, respectively, to keep in the initial low state before generating a POR. The POR 300 can also include de-coupling capacitor 348 in a buffer block 340 coupled to VDD to keep PORB high during ramping before the POR is triggered.

In FIG. 5(b), the SA bias circuit 310 is a PTAT to generate a current source proportional to absolute temperature in a CMOS technology. The PMOS 312 can have a PTAT current mirrored to a PMOS 321 to generate a reference voltage Vip through a reference resistor 323 in serial to a diode-connected NMOS 322 in the reference branch. Similarly, the PMOS 312 can also have a PTAT current mirrored to a PMOS 331 to generate a target voltage Vin through a target resistor 333 in serial to a diode-connected NMOS 332 in the target branch. The target branch is a portion of the SA reference/target circuit 320. For example, the reference and the target resistors 323 and 333 can have resistance of about 12K and 11K, respectively, to provide a pair of reference and target voltages higher enough for the current-mirrored SA to sense correctly. It is crucial to generate a pair of voltages using similar device configurations but with small differences in parameters to make the follow-on current-mirrored SA in the SA 330 to work properly. The SA 330 has a current-mirrored sense amplifier to sense the voltage difference between the reference and the target branches, Vip and Vin, respectively, and output a high voltage signal in SAOUT. The SA output SAOUT can go through a buffer block 340 that has two stages of inverters 341 and 342 to provide buffers and to generate a PORB and POR, respectively. The PORB and POR can be used as EN and ENB, respectively, to power down at least one of the SA bias circuit 310, the SA reference/target circuit 320, and the SA 330 in one embodiment. The POR or SAOUT can also go through a power-off block (not shown in FIG. 5(b)) to generate EN and ENB to power down the at least one of the SA bias circuit 310, the SA reference/target circuit 320, and the SA 330 in another embodiment.

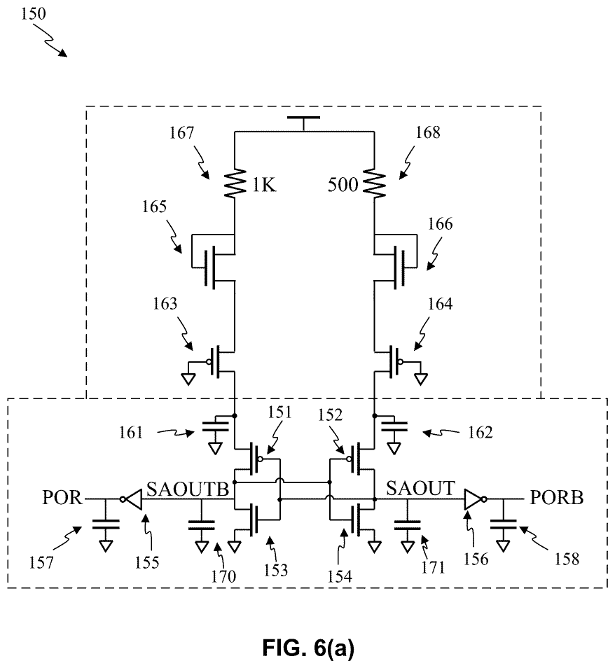

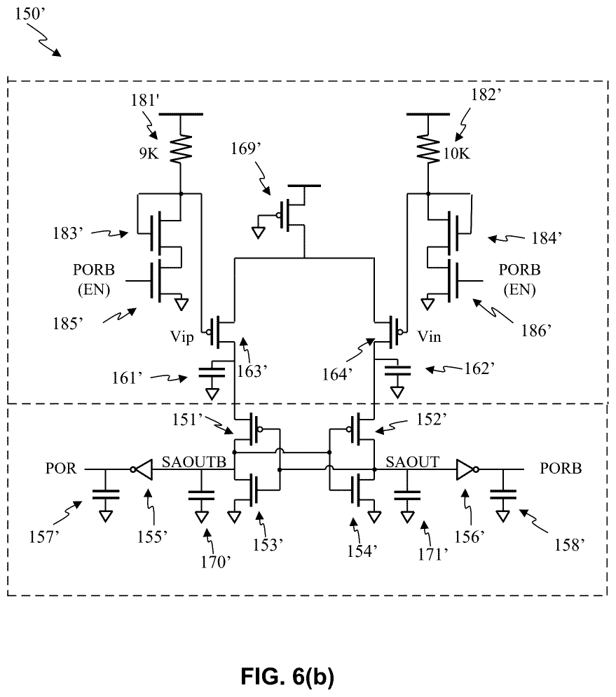

FIG. 6(a) show a portion of a schematic of a POR 150 based on a latch-type of sense amplifier (SA), corresponding to FIG. 4, according to another embodiment of the invention. The POR 150 has a cross-coupled latch comprising a pair of NMOS 153 and 154 with sources coupled to GND and their drains SAOUTB and SAOUT coupled to drains of another pair of PMOS 151 and 152, respectively. The gates of PMOS 151 and NMOS 153 are coupled together and then coupled to the drain SAOUT of the PMOS 152 and NMOS 154. Similarly, the gate of PMOS 152 and NMOS 154 are coupled together and then coupled to the drain SAOUTB of the PMOS 151 and NMOS 153, respectively. The sources of the PMOS 151 and NMOS 153 are coupled to drains of a pair PMOS cascode devices 163 and 164, respectively. Their sources are coupled to sources of diode-connected NMOS 165 and 166, respectively. The gates and drains of NMOS 165 and 166 are coupled to a reference 167 and a target resistor 168 to VDD, respectively. The reference 167 and target resistance 168 are 1K and 500 ohms, respectively, for the purpose of discussion. The gates of the cascode PMOS 163 and 164 are coupled to GND. The SA output nodes SAOUT and SAOUTB are coupled to input of the inverters 156 and 155, respectively, to generate output PORB and POR, respectively. There are decoupling capacitors 157, 158, 161, 162, 170, and 171 to hold the major SA nodes to GND and to prevent those nodes from following VDD ramping up. The diode-connected NMOS 165 and 166 can be omitted in another embodiment.

FIG. 6(a) shows a POR circuit that can operate as follows. All the major nodes, such as SA output SAOUT/SAOUT, SA buffer output POR/POR, and the sources and drains of the cascode PMOS 163 and 164 are held to GND. When VDD ramps up to around Vtn+|Vtp|, the cascode PMOS 163 and 164 start to turn on and to sense the resistance difference between the reference 167 and the target 168 resistors. SAOUTB goes low and POR goes high accordingly.

FIG. 6(b) show a portion of a schematic of a POR generation 150′ based on a latch-type of sense amplifier (SA), corresponding to FIG. 4, according to another embodiment of the invention. The POR generation 150′ has a cross-coupled latch comprising a pair of NMOS 153′ and 154′ with the sources coupled to GND and their drains SAOUTB and SAOUT coupled to drains of another pair of PMOS 151′ and 152′, respectively. The gates of 151′ and 153′ are coupled together and then coupled to the drain SAOUT of the 152′ and 154′. Similarly, the gates of 152′ and 154′ are coupled together and then coupled to the drain SAOUTB of the 151′ and 153′. The sources of the PMOS 151′ and 152′ are coupled to drains of a differential pair PMOS 163′ and 164′, respectively, whose sources are coupled to a drain of a tailing PMOS 169′ and gates are coupled to differential input Vip and Vin, respectively. The tailing PMOS 169′ has a gate coupled to GND and source coupled to VDD. The differential input has a pair of resistors 181′ and 182′ coupled to VDD and Vip and Vin, respectively. The nodes Vip and Vin are further coupled to a pair of diode-connect NMOS 183′ and 184′, respectively, whose sources are coupled to drains of a pair of NMOS 185′ and 186′, respectively, to cutoff power after a POR is generated. The sources of NMOS 185′ and 186′ are coupled to GND and their gates are coupled to PORB (ENB). There are decoupling capacitors 157′, 158′, 161′, 162′, 170′, and 171′ to hold the major SA nodes to GND and to prevent those nodes from following VDD during ramping up. The diode-connected NMOS 183′ and 184′ can be omitted or replaced by another pair of devices to control the trigger voltage in another embodiment.

FIG. 6(b) shows a POR circuit 150′ works as follows. All the major nodes, such as SA output SAOUT/SAOUT, SA buffer output POR/POR, and the sources and drains of the differential pair PMOS 163′ and 164′ are held to GND by decoupling capacitors. When VDD ramps up to around Vtn+|Vtp|, the differential pair PMOS 163′ and 164′ start to turn on and to sense the voltage difference between Vip and Vin due to the resistance difference between the reference 181′ and the target 182′. SAOUTB goes low and POR goes high accordingly. The POR circuit 150′ FIG. 6(b) is very similar to the POR circuit 150 in FIG. 6(a) except that a differential pair rather than a cascode SA is used to sense differential voltages due to different resistances. The resistance shown in FIG. 5(a), 5(b), 6(a) or 6(b) are for discussion purposes only. Their values may vary depending on the MOS devices sizes and MOS processing technologies.

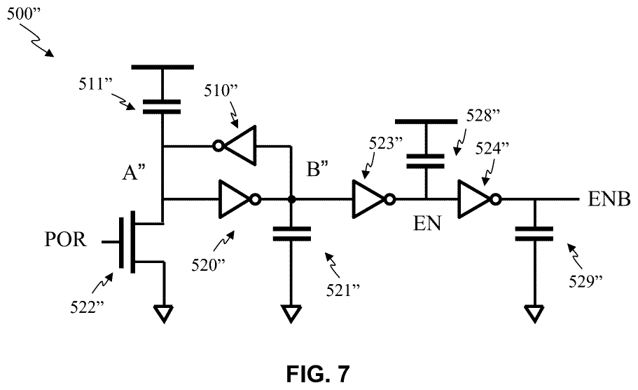

FIG. 7 shows a portion of a power-off circuit 500″, corresponding to FIG. 4, that can be used to cut off the power of the at least one of the SA bias circuit, the SA reference circuit, and the SA shown in FIG. 5(a), 5(b), or 6(b), according to one embodiment of the invention. The power-off circuit 500″ can be a re-trigger POR circuit to provide better isolation between turning on a POR and turning off the at least one of the SA bias circuit, the SA reference/target circuit, and the SA. The power-off circuit 500″ has a cross-coupled inverters 510″ and 520″ with two nodes B″ and A″. The node B″ has a capacitor 521″ coupled to GND and the node A″ has another capacitor 511″ coupled to VDD. Node A″ has a pulldown NMOS 522″ with a gate coupled to a POR. The node A″ and B″ can be coupled to VDD and GND, respectively, when VDD is ramping up. Node A″ can be pulled down to GND when a POR is generated to pull the node A″ low and to flip the node B″ high. The node B″ can go through two stages of inverter 523″ and 524″ to generate EN and ENB signals, corresponding to the signals EN and ENB in FIG. 5(a), 5(b), or 6(b), respectively. The capacitors 528″ and 529″ can be coupled to VDD and GND, respectively, to keep the initial logic states until a POR is generated. The nodes A″ and B″ can be used as EN and ENB without inverters 523″ and 524″ buffering, respectively, in another embodiment.

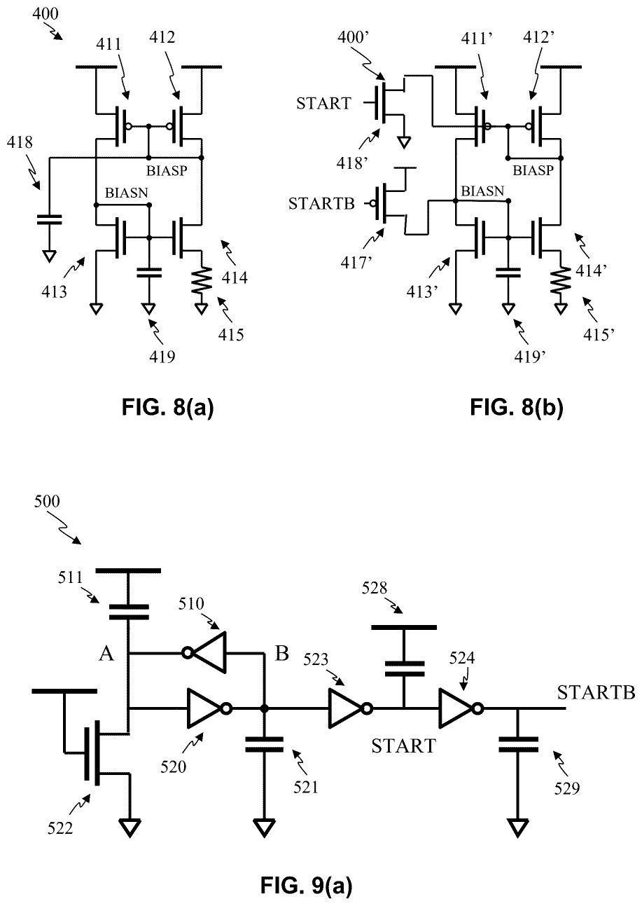

The SA bias circuit 310 in the POR 300 in FIG. 5(b) has a pair of cross-coupled PMOS and NMOS in the SA bias 310 that needs a startup circuit to initialize the PTAT circuit 310 into an active state. FIG. 8(a) shows a portion of a schematic of a startup circuit 400, corresponding to 310 in FIG. 5(a), according to one embodiment. The left branch of the CMOS PTAT 400 has a PMOS 411 with source, gate, and drain coupled to VDD, BIASP and BIASN, respectively. NMOS 413 has a source, gate, and drain coupled to GND, BIASN, and BIASN, respectively. The right branch has a PMOS 412 with source, gate, and drain coupled to VDD, BIASP, and BIASP, respectively. The NMOS 414 has source, gate, and drain coupled to a bias resistor 415, BIASN, and BIASP, respectively. The bias resistor 415 has the other end coupled to GND. A capacitor 418 coupled between BIASP and GND can be used as a startup circuit when the ramping rate is not too slow, e.g. faster than 10 ms. During VDD ramping, the gate of the PMOS 412 can be coupled low by the capacitor 418 to conduct a current in PMOS 412 and to initialize the PTAT 400 into an active state.

FIG. 8(b) shows a portion of a schematic of a startup circuit 400′, corresponding to the SA bias circuit 310 in a POR 300 in FIG. 5(b), according to one embodiment. The left branch of the CMOS PTAT 400′ has a PMOS 411′ with source, gate, and drain coupled to VDD, BIASP and BIASN, respectively. NMOS 413′ has source, gate, and drain coupled to GND, BIASN, and BIASN, respectively. The right branch has a PMOS 412′ with source, gate, and drain coupled to VDD, BIASP, and BIASP, respectively. The NMOS 414′ has a source, gate, and drain coupled to a bias resistor 415′, BIASN, and BIASP, respectively. The bias resistor 415′ has the other end coupled to GND. A NMOS pulldown 418′ can be coupled to BIASP and a PMOS pullup 417′ can be coupled to BIASN with gates coupled to START and STARTB, respectively. The START and STARTB can be a pulse and a pulse inverted, respectively, to startup a PTAT bias during VDD ramping.

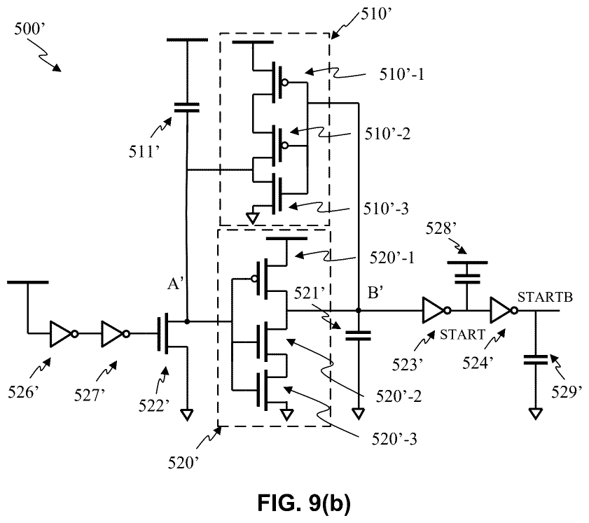

FIG. 9(a) shows a portion of a schematic of a startup generation circuit 500, corresponding to FIG. 8(b), according to one embodiment of the invention. The startup circuit 500 is similar to a POR circuit as shown in FIG. 5(a) or 5(b), except that the POR turn-on voltage can be only 0.3˜0.6V, below one Vtn or |Vtp|, which is not suitable to be used as a POR practically. However, this circuit 500 is well enough to be used as a startup, corresponding to PTAT in FIG. 8(b). The startup generation circuit 500 has a cross-coupled inverters 510 and 520 with two nodes B and A. The node B has a capacitor 521 coupled to GND and the node A has another capacitor 511 coupled to VDD. Node A has a pulldown NMOS 522 with gate coupled to VDD. The nodes A and B will be coupled to VDD and GND, respectively, when VDD is ramping up. But node A can be pulled down to GND when VDD is higher than one Vtn to pull node A low and to flip the node B high. The node B can go through two stages of inverter 523 and 524 to generate START and STARTB signals, corresponding to the same signals in FIG. 8(b), respectively. The capacitors 528 and 529 can be coupled to VDD and GND, respectively, to keep in the initial states until VDD voltage is higher enough to pulldown node A. Node A and B can be used as START and STARTB, respectively, without the inverters 523 and 524, in another embodiment.

FIG. 9(b) shows a portion of a startup generation circuit 500′, according to another embodiment of the invention. The startup generation circuit 500′ has a cross-coupled inverters 510′ and 520′ with two nodes B′ and A′. The node B′ has a capacitor 521′ coupled to GND and the node A′ has another capacitor 511′ coupled to VDD. Node A′ has a pulldown NMOS 522′ with a gate coupled to VDD through two inverters 526′ and 527′ delays. The inverter 510′ can have two small PMOS 510′-1 and 510′-2 stacked as a pullup and a larger NMOS 510′-3 pulldown to provide a higher node B′ turn-on voltage. Similarly, the inverter 520′ can have a larger PMOS 520′-1 pullup and two NMOS 520′-2 and 520′-3 stacked pulldown to provide a higher node A′ turn-on voltage. The nodes A′ and B′ can be coupled to VDD and GND, respectively, when VDD is ramping up. Node A′ can be pulled down to GND when VDD, through two inverter 526′ and 527′ delays, is higher than one Vtn to pull node A′ low and to flip the node B′ high. The node B′ can go through two stages of inverter 523′ and 524′ to generate START and STARTB signals, corresponding to the same signals in FIG. 8(b), respectively. The capacitors 528′ and 529′ can be coupled to VDD and GND, respectively, to keep in the initial states until node B′ is flipped high. Nodes A′ and B′ can be used as START and STARTB, respectively, without the inverters 523′ and 524′, in another embodiment.

FIGS. 5(a), 5(b), 6(a), and 6(b) show many decoupling capacitors to hold SA vital nodes to GND before VDD ramping up. The decoupling capacitors can be any kinds of metal-oxide-metal (MOM), metal-insulator-metal (MIM), poly-insulator-poly (PIP), MOS capacitor, etc. The most desirable decoupling capacitors can be a MOS operating in accumulation mode, such as NMOS on N-well, or called varactor. This kind of MOS capacitor tends to have high capacitance per area and are available in almost all CMOS technologies. However, the area for all the decoupling capacitors can still be very larger, if the ramping rate is very slow, such as 1 sec. In this case, there can be another embodiment to reduce the decoupling capacitor sizes. At least one of the decoupling capacitors can be replaced by a small NMOS whose drain is coupled to the node to be decoupled, source to GND, and gate to a START signal, corresponding to START in FIG. 9(a) or 9(b), if available. Essentially, the START signal can be used to hold the major SA nodes to GND during VDD ramping. With some or all of the decoupling capacitors replaced by small NMOS devices with gates coupled to START, the POR response time can be faster. Other than reducing the capacitor area, this can help Brown-Out Reset (BOR). When there is a dip in VDD, the charges on the POR circuit can be quickly discharged, due to fewer and smaller decoupling capacitors, so that the POR can be re-triggered after VDD goes high again.

FIGS. 4-9(b) only show a few of many possible embodiments of a Power-On Reset (POR), startup circuit, power-off circuit, and startup generation circuit. The SA bias, SA reference, SA target, and SA can have many different variants and yet equivalent embodiments. The diode-connected MOS for bias generation can be NMOS or PMOS. The reference voltages can be generated from NMOS or PMOS current mirrors. The PTAT in SA bias can include CMOS, diode, or bipolar. The SA can be a cascode, current-mirrored, or latch-type of sense amplifier. The cascode device for amplification can be NMOS or PMOS. The input to a current-mirrored SA can be NMOS or PMOS. The SA output buffer can include inverters, Boolean gates, or Schmidt triggers to provide sharp transition. The SA output buffer can also include a power-off circuit to further sharpen the signal and to provide isolation between turning on POR and turning off the at least one of the SA bias, SA reference, SA target, and SA. There are many variations and equivalent embodiments for generating a SA-based POR and they are all within the scope of this invention.

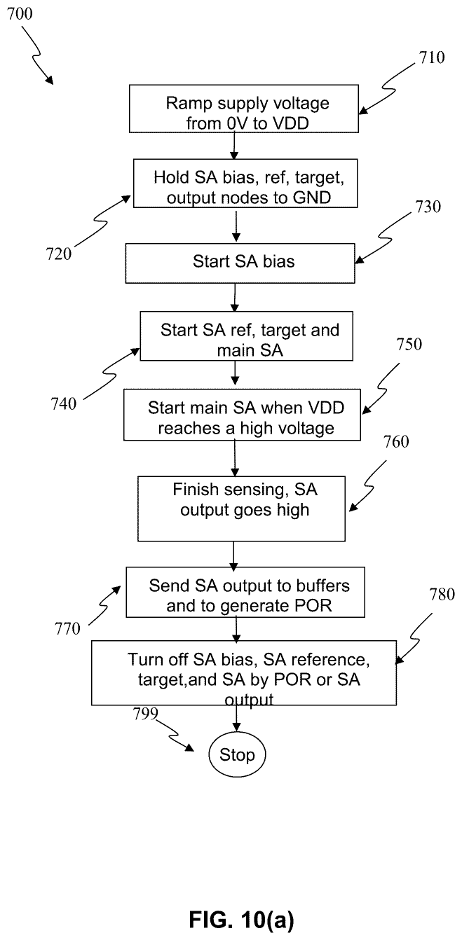

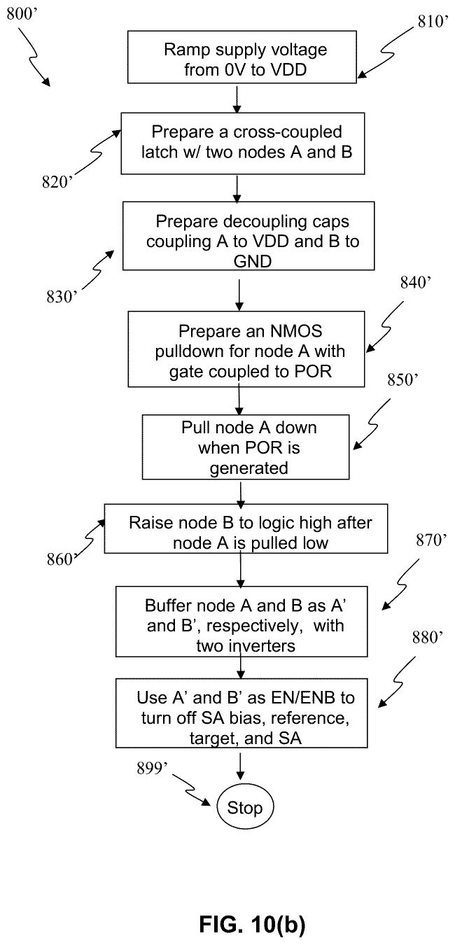

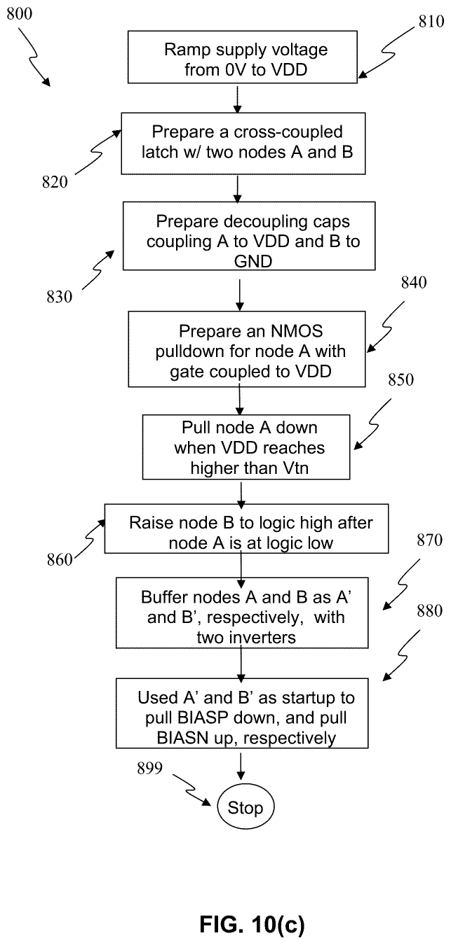

FIG. 10(a) shows a flow chart of a procedure 700 to generate a POR, corresponding to FIG. 4, 5(a), 5(b), 6(a) or 6(b), according to one embodiment. The procedure 700 starts by ramping up a supply voltage from OV to VDD in step 710. Hold the major nodes in SA bias, SA reference, SA target, and SA output to GND in step 720 by using decoupling capacitors to GND or a startup signal to pulldown NMOS devices. Then, start SA bias to generate bias signals for SA reference, SA target, and SA in step 730. The SA bias signal starts SA reference, SA target, and main SA in step 740. Once the SA bias and SA reference/target are ready, the main SA can start to sense any resistance, current, or voltage difference between the reference and the target branches in SA when VDD reaches a voltage higher enough in step 750. After sensing finishes, SA output can rise from 0V to a logic high in step 760. The SA output can go through buffers to provide delays and to sharpen the waveform to generate a POR in step 770. Then, the SA bias, SA reference/target, and SA can be turned off after a POR is generated by using POR/PORB signals or going through a power-off circuit in step 780. Then the POR generation procedure finishes in step 799.

FIG. 10(b) shows a flow chart of a procedure 800′ to generate power-off signals, corresponding to FIG. 4, 5(a), 5(b), 6(b), or 7, to cutoff the power of the at least one of the SA bias, SA reference, SA target, and SA after a POR is generated. The procedure 800′ starts by ramping a supply voltage from 0V to VDD in step 810′. A cross-coupled latch with two nodes A and B can be prepared in step 820′. Two decoupling capacitors, one coupling the node A to VDD and the other coupling the node B to GND, can be prepared to hold the initial state during VDD ramping in step 830′. Then, an NMOS pulldown to node A with a gate coupled to a POR can be prepared in step 840′. When a POR is generated from 0V to a logic high voltage, node A can be pulled low in step 850′. Subsequently, node B can be flipped to logic high in step 860′. Node B can go through inverters to generate A′ and B′ in the first and second inverters output, respectively, in step 870′. The signals A′ and B′ can be used as EN and ENB, corresponding to FIG. 5(a), 5(b), or 6(b) to cutoff the power of SA blocks in step 880′. Then the SA blocks, such as SA bias, SA reference, SA target and SA are all powered off and the procedure stops at step 899′.

FIG. 10(c) shows a flow chart of a procedure 800 to generate startup signals to initialize a PTAT into an active state. The procedure 800 starts by ramping a supply voltage from 0V to VDD in step 810. A cross-coupled latch with two nodes A and B can be prepared in step 820. Two decoupling capacitors, one coupling node A to VDD and the other coupling node B to GND, can be prepared to provide an initial state during VDD ramping in step 830. Then, prepare an NMOS pulldown to node A with gate coupled to VDD or VDD with some buffer delays in step 840. When VDD reaches a voltage higher than Vtn, node A can be pulled low in step 850. Subsequently, node B can be flipped to logic high in step 860. Node B can go through inverters to generate an output A′ and B′ in the first and second inverters output, respectively, in step 870. The signals A′ and B′ can be used to pull BIASP low and to pull BIAN high, respectively, in a PTAT bias, corresponding to FIG. 8(b), 9(a), or 9(b). Then, after the startup signals are generated, the procedure stops at step 899.

The procedures of generating a POR, startup signals, or power down signals in FIGS. 10(a)-10(c) are for illustrative purposes. The detailed implementation in the procedures may vary. For example, some steps may be omitted. Some steps can be re-arranged in different orders and they are all within the scope of this invention.

The above discussions are for illustrative purposes to exemplify some embodiments of the present invention. The block diagrams of the SA bias circuit, the SA reference circuit, the SA target circuit, and the SA shown in FIG. 4, 5(a), 5(b), 6(a), or 6(b) are only a few of many possible embodiments. There can be many different types or circuit configurations of SA bias circuit such as diode-connected or PTAT for current mirroring. The SA reference circuit can be resistance, voltage, or current reference branch to be compared with something similar in a target branch for a main SA to sense the difference correctly. The SA can be fully static, such as a cascode or current mirrored, or a dynamic. SA, such as latch type of SA. The sensing devices can be NMOS or PMOS. Similarly, the schematics of the power-off or startup circuits shown in FIGS. 7 and 8(a)-9(b) are only a few of many possible embodiments. The startup signals can be any positive or negative pulse to initialize any latch-type of bias circuit, such as PTAT, into an active state. The SA power down signals can be generated from a POR-like circuit triggered by POR, instead of VDD or VDD with delays to a gate of a NMOS pulldown, as shown in FIG. 7. The startup pulses can be generated from a POR-like circuit block with further buffering as shown in FIGS. 9(a), 9(b). The detailed implementation may vary. There can be many different embodiments of layout, circuit, logic, architecture, methods, and procedures and that they are still within the scope of this invention for those skilled in the art.

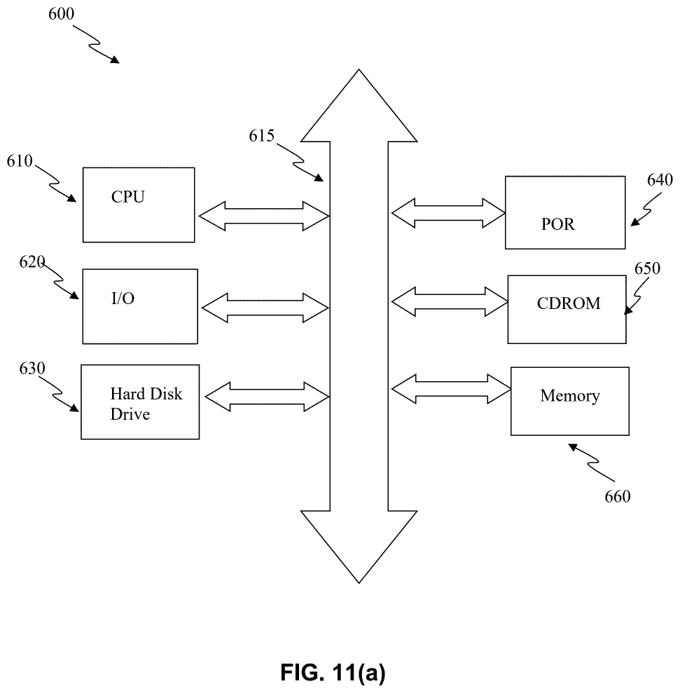

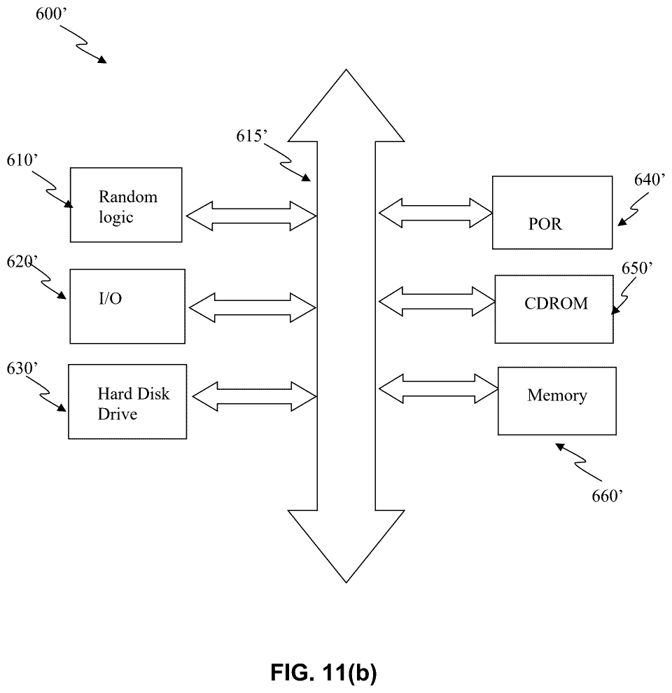

FIG. 11(a) shows a processor electronic system 600 that employees at least one POR block 640, according to one embodiment. The processor system 600 can, for example, pertain to an electronic system. The electronic system can include a Central Process Unit (CPU) 610, which communicates through a common bus 615 to various memory and peripheral devices such as I/O 620, hard disk drive 630, CDROM 650, POR block 640, and memory 660. Memory 660 can be any memory such as SRAM, DRAM, ROM, OTP, flash, or programmable resistive memory, typically interfaces to CPU 610 through a memory controller. CPU 610 generally is a microprocessor, a digital signal processor, or other programmable digital logic devices. The POR block 640 is preferably constructed as an integrated circuit, which includes at least one sense amplifier bias circuit, a reference circuit, a target circuit, and a sense amplifier, in accordance with any of the embodiment of the POR implementations discussed herein. The POR block 640 typically interfaces to CPU 610 or any other logic blocks in 600 through a simple bus to reset latches, flip-flops, or state machines and to initialize a system. If desired, the POR block 640 may be combined with the processor, for example CPU 610, in a single integrated circuit.

FIG. 11(b) shows an electronic system 600′ that employees at least one POR block 640′, according to another embodiment. The electronic system can include a random logic block 610′, which communicate through a common bus 615′ to various memory and peripheral devices such as I/O 620′, hard disk drive 630′, CDROM 650′, POR block 640′, and memory 660′. Memory 660′ can be any memory such as SRAM, DRAM, ROM, OTP, flash, or programmable resistive memory, typically interfaces to random logic block 610 through a memory controller. Random logic block 610′ generally can be blocks of glue logic that is commonly generated by automated logic design flow. The POR block 640′ is preferably constructed as an integrated circuit, which includes at least one sense amplifier bias circuit, a reference circuit, a target circuit, a sense amplifier, and output buffers, in accordance with any of the embodiment of the POR implementations discussed herein. The POR block 640′ typically interfaces to random logic 610′ or any other blocks in 600′ through a simple bus to reset latches, flip-flops, or state machines and to initialize a system. If desired, the POR block 640′ may be combined with the random logic 610′, in a single integrated circuit.

The various embodiments of the invention disclosed herein can implement one or more of the desired characteristics of a POR. Some desired characteristics of a POR are noted below:
Precision turn-on voltage insensitive to temperature and process variations, wide ramping time rate, low transient current and zero standby current, small area and brown out reset (BOR)—to detect sudden VDD drop and to re-start a POR to reset system, etc.
To serve the purposes of resetting a system, a POR can have a turn-on voltage that is higher than a pre-determined voltage. Usually, this voltage is higher than one Vtn or |Vtp| and lower than 2 times of Vtn or |Vtp|. For example, a desired POR turn-on voltage is around 0.9˜1.3V for a 1.8V VDD ramping. This turn-on voltage should be temperature insensitive, such as within 0.2˜0.3V variations over temperature from −40 C to 125 C and different process skewed corners, and different ramping rates.
It is also advantageous for a POR to have wide VDD ramping rates. The ramping rate depends on the electronic systems. If an old and bulky system that uses old electronic parts, the capacitance loadings to the power supplies tend to be large, and the VDD ramping time can be from 10 ms to 100 ms. If a new and portable electronic system that uses newer parts, the VDD ramping time could be 10 us to 1 ms, with 100 us as a nominal ramping time. To target any electronic systems, the preferred VDD ramping time would be from 1 ns to 1 sec. This would impose very severe circuit design restrictions such that a POR is better to be triggered by a voltage threshold rather than a RC time constant.
It is also advantageous for a POR to have very low standby current, other than junction or device leakage, and has transient current as low as possible. In today's prevailing CMOS technologies, zero standby current is a must that all devices should be turned off after POR is generated. This involves a self-timed circuit to cut off all circuits after POR is properly generated.
It is also desirous for a POR to require only a small amount of area, such as within an integrated circuit layout. Small area means low costs. Hence, exotic devices such as bipolar devices or diodes should be avoided. Complicated analog circuits such as OPAMP, analog comparator, or bandgap reference circuits should be avoided. Instead, logic circuits should be preferrable used.
Lastly, another desirable characteristic for a POR is Brown-Out Reset (BOR) to re-generate a POR after a VDD dip occurs. This means a capability to re-generate a POR after VDD is detected a dip to a predetermined value or to ground. During VDD dipping, latches or flip-flop may change data so that a system reset is desirable to ensure reliable operations, if the VDD dips last for more than 1 us as an example.

The above description and drawings are only to be considered illustrative of exemplary embodiments, which achieve the features and advantages of the present invention. Modifications and substitutions of specific process conditions and structures can be made without departing from the spirit and scope of the present invention.

The many features and advantages of the present invention are apparent from the written description and, thus, it is intended by the appended claims to cover all such features and advantages of the invention. Further, since numerous modifications and changes will readily occur to those skilled in the art, it is not desired to limit the invention to the exact construction and operation as illustrated and described. Hence, all suitable modifications and equivalents may be resorted to as falling within the scope of the invention.

It will be apparent to those skilled in the art that various modifications and variations can be made in the present invention without departing from the spirit or scope of the inventions. Thus, it is intended that the present invention covers the modifications and variations of this invention provided they come within the scope of the appended claims and their equivalents.

What is claimed is:

1. A Power-On Reset (POR) circuit block integrated in an integrated circuit, the POR circuit block comprising:
at least one sense amplifier (SA) bias circuit;
at least one sense amplifier (SA) reference circuit coupled to the SA bias circuit and configured to produce a reference signal;
at least one sense amplifier (SA) target circuit coupled to the SA bias circuit and configured to produce a target input signal; and
at least one sense amplifier circuit coupled to the SA reference circuit to receive the reference signal and coupled to the SA target circuit to receive the target input signal, the at least one sense amplifier circuit configured to provide a SA output signal based on a comparison of the reference signal and the target input signal.

2. The POR circuit block as recited in claim 1, wherein the SA output signal is or produces a POR signal that initiates a POR after a supply voltage VDD ramps up from approximately 0V to a pre-determined voltage to thereby cause the SA output signal and the POR signal to be raised to a high voltage abruptly.

3. The POR circuit block as recited in claim 1,
buffer circuitry operatively connected to the at least one sense amplifier, the buffer circuity is configured to buffer the SA output signal to output the POR signal.

4. The POR circuit block as recited in claim 1, wherein the POR circuit block generates a POR signal based on the SA output, which transitions, from about 0 Volts to about VDD when a supply voltage VDD ramps up from approximately 0 Volts to a predetermined voltage.

5. The POR circuit block as recited in claim 1, wherein the POR circuit block comprises:
buffer circuitry operatively connected to the at least one sense amplifier, the buffer circuity is configured to buffer the SA output signal to output the POR signal.

6. The POR circuit block as recited in claim 1, wherein the reference signal comprises a resistance, current, or voltage reference.

7. The POR circuit block as recited in claim 1, wherein the SA bias circuit comprises a diode-connected MOS for current mirroring.

8. The POR circuit block as recited in claim 1, wherein the SA bias circuit comprises a Proportional To Absolute Temperature (PTAT) circuit that generates bias signals, BIASP and BIASN, to bias PMOS or NMOS in the PTAT properly.

9. The POR circuit block as recited in claim 1, wherein the at least one sense amplifier comprises a cascode amplifier.

10. The POR circuit block as recited in claim 1, wherein the at least one main sense amplifier comprises a current-mirrored amplifier.

11. The POR circuit block as recited in claim 1, wherein the at least one main sense amplifier comprises a latch-type of SA that has a cross-coupled latch, with sources of one or more NMOS devices coupled to GND and with sources of one or more PMOS devices coupled to drains of a pair of one or more cascode devices or differential pair devices.

12. The POR circuit block as recited in claim 1, wherein the at least one of the at least one SA bias circuit, the at least one SA reference circuit, the at least one SA target circuit, and the at least one of the main SA has its output coupled to ground GND through at least one decoupling capacitor.

13. The POR circuit block as recited in claim 1,
wherein the SA bias circuit has a startup circuit comprising at least one cross-coupled latch with two nodes A and B, the node A having a capacitor couped to VDD and the node B having another capacitor coupled to GND, the node A having an NMOS pulldown to GND with gate coupled to VDD directly or via one or more Boolean gates as buffers, and
wherein the node A is pulled low and node B pulled high during the VDD ramping up to a pre-determined values to serve as startup signals to pulldown BIASP and pullup BIASN in a PTAT circuit, respectively.

14. The POR circuit block as recited in claim 1, wherein the at least one of SA bias circuit, the SA reference circuit, the SA target circuit, or the main SA circuit has output coupled to ground GND through at least one NMOS pulldown with the gate coupled to at least one startup signal.

15. The POR circuit block as recited in claim 1, wherein the POR comprises:
at least one power-down block to generate at least one enable (EN) and/or enable bar (ENB) signals to power-off the at least one SA blocks; and
at least one cross-coupled latch with two nodes A and B,
wherein the node A has a capacitor couped to VDD and the node B has another capacitor coupled to GND,
wherein the node A has an NMOS pulldown to GND with gate coupled to the POR signal, and
wherein the node A is pulled low and node B pulled high after POR signal rises to a high voltage during VDD ramping to serve as EN and ENB, respectively.

16. The POR circuit block as recited in claim 15, wherein the POR signal is generated when a supply voltage VDD reaches to a predetermined voltage of between about 0.9V to 1.5V.

17. An electronic system, comprising:
a processor or a random logic block; and
at least one Power-On Reset (POR) circuit block operatively connected to the processor or random logic, the at least one POR circuit block comprising:
at least one sense amplifier (SA) reference circuit configured to produce a reference signal;
at least one sense amplifier (SA) target circuit configured to produce a target input signal; and
at least one sense amplifier circuit coupled to the SA reference circuit to receive the reference signal and coupled to the SA target circuit to receive the target input signal, the at least one sense amplifier circuit configured to provide a SA output signal based on a comparison of the reference signal and the target input signal.

18. The electronic system as recited in claim 17, wherein the at least one POR circuit block comprises:
at least one buffer block coupled to the SA output, the at least one buffer block producing a POR signal based on the SA output.

19. The electronic system as recited in claim 17,
wherein the electronic system comprises at least one latch or flip-flop in the processor or random logic block, and
wherein the POR signal is configured to reset the at least one latch or flip-flop in the processor or random logic block.

20. The electronic system as recited in claim 19, wherein the POR signal is generated when the supply voltage VDD reaches to a pre-determined value of between 0.9 to 1.5V.

21. The electronic system as recited in claim 17,
wherein the at least one POR circuit block comprises:
at least one sense amplifier (SA) bias circuit to provide a bias input,
wherein at least one of the at least one SA reference circuit and the at least one SA target circuit are coupled to the SA bias circuit to receive the bias input, and
wherein at least one of the reference signal and the target signal are dependent on the bias input.

22. The electronic system as recited in claim 17, wherein the SA bias comprises a diode-connected MOS for current mirroring.

23. The electronic system as recited in claim 17, wherein the at least one sense amplifier circuit comprises a cascode or current mirrored amplifier.

24. The electronic system as recited in claim 17, wherein the sense amplifier circuit comprises a latch-type of SA that has a cross-coupled latch, with sources of NMOS coupled to GND and sources of PMOS coupled to drains of a pair of cascode devices or differential pair devices.

25. The electronic system as recited in claim 17, wherein the SA bias circuit comprises a PTAT, Proportional To Absolute Temperature circuit, that generates bias signals, BIASP and BIASN, to bias PMOS or NMOS of the PTAT properly for the SA reference or SA.

26. The electronic system as recited in claim 17,
wherein the SA bias circuit includes at least a startup circuit comprising at least one cross-coupled latch with two nodes A and B, with the node A having a capacitor couped to VDD and with the node B having another capacitor coupled to GND, the node A having an NMOS pulldown to GND with gate coupled to VDD directly or via one or more Boolean gates, and
wherein the node A is pulled low and node B pulled high during the VDD ramping up to a pre-determined value to serve as startup signals to pulldown the BIASP and pullup the BIASN, respectively.

27. A method for providing a Power-On Reset (POR) signal in an integrated circuit, the method comprising:
producing a bias input;
producing a reference signal based on the bias input;
producing a target signal based one the bias input; and
generating, via at least a sense amplified circuit included within the integrated circuit, the sense amplifier output signal based on at least the reference signal and the target signal,
wherein the POR signal is configured to transition from approximately 0V to approximately VDD abruptly when a supply voltage VDD ramps up from 0V to a pre-determined value.
